(19) United States
(12) Patent Application Publication
(10) Pub. No.: US 2025/0259674 A1
(43) Pub. Date: Aug. 14, 2025

(54) LOW-POWER STATIC RANDOM ACCESS MEMORY USING WRITE AMPLIFIER

(71) Applicant: UNTETHER AI CORPORATION, Toronto (CA)

(72) Inventors: William Martin SNELGROVE, Toronto (CA); Katsuyuki SATO, Tokyo (JP)

(21) Appl. No.: 19/052,906

(22) Filed: Feb. 13, 2025

Related U.S. Application Data
(60) Provisional application No. 63/553,187, filed on Feb. 14, 2024.

(51) Int. Cl. G11C 11/419

(52) U.S. Cl. CPC G11C 11/419

(57) ABSTRACT

A low-power static random access memory (SRAM) for at-memory architecture is set forth. The on-chip SRAM in at-memory architecture is located adjacent to PE (Processing Element) so that the same voltage as PE, vddp, is required at the SRAM circuit connected to PE. Further lower bitline precharge voltage, around 0.1V, than vddp is designed by smart charge sharing method using appropriate segmented bit lines. On the other hand, SRAM write operation needs higher voltage than PE. To generate such high writing voltage from din voltage which is generated by vddp of PE, write main amplifier which is located at the opposite side of read main amplifier which is located next to PE is designed. In addition, seamless read operation without any segmented sub arrays, and separated read and write MA (Main Amplifier) are proposed.

### BACKGROUND OF THE INVENTION

### 1. Field of the Invention

The present invention is directed to static random access memory (hereinafter SRAM), and more particularly to an on-chip SRAM that is located adjacent to the processing element (PE) of an at-memory compute architecture.

### 2. Description of the Related Art

There is a recognized need to reduce power dissipation in traditional SRAMs (e.g. Vdd supply voltage of 0.5 V or less), wherein a plurality of memory cells along a selected word-line are read or written via a bit line. Recently, this need has become more pressing with the introduction of emerging SRAMs used in artificial intelligence (AI) chips, wherein all of the memory cells are simultaneously read or written for massively parallel operations between processor element blocks and the SRAMs.

International patent application No. PCT/IB2022/055760 naming Sato, K et al., and entitled LOW-POWER STATIC RANDOM ACCESS MEMORY USING HALF VDD PRECHARGE, sets forth a method and apparatus for half-Vdd bit line precharge of six-transistor (6T SRAM) memory cells to reduce the bit line precharge power, compared to conventional prior art Vdd bit line precharge approaches. As disclosed in PCT/IB2022/055760, a 6T SRAM memory cell is arranged between a first bitline (BL), a second bitline (BLB) and a word line. A bitline precharge circuit precharges the first bitline and second bitline to a voltage of Vdd/2 prior to the 6T SRAM memory cell receiving a word line signal.

At-memory compute architectures have attracted attention in recent years (see Bob Beachler, “The Advantages of At-Memory Compute for AI Inference”, EETimes, Jan. 24, 2022). In contrast with the traditional von Neumann architecture having external DRAM, a cache, and a pipeline to access processing elements, an at-memory compute architecture has the processing elements (PEs) directly attached to the memory cells of a 6T SRAM to achieve high bandwidth interaction between processing element and SRAM. As the name implies, a key characteristic of the at-memory architecture is the physical connection between the processing elements “at the memory” that feeds them. Increasing demand for high TOPS/W for AI hardware acceleration requires compute hardware having high throughput under low power consumption (TOPS/W is a metric indicating how many computing operations an AI accelerator can handle in one second at 100% utilization). The processing element, which is the basic core unit of the compute hardware, needs to operate at lower voltages (e.g. 0.35˜0.4V) in order to reduce power. Hence, the operational voltage of the 6T SRAM, which is attached to the processing elements, is required to be reduced to the same voltage as that of the processing element. The power consumption of the bit line (BL) precharge circuit is a major contributor to the power consumption of the 6T SRAM.

Writing a voltage into the data line (din) of an SRAM 6T bit cell sets the bit cell to the that voltage. Generally speaking, reliability of SRAM data hold and read operations increases with a high bit cell voltage, for example, 0.7V of cell vdd voltage in case of 0.4V of PE operation. In case of 0.4V of PE operation, din voltage will be set as the same voltage of PE, that is, 0.4V. The writing voltage to the bit cell should be the same voltage as cell vdd, that is, 0.7V in this example. Therefore, the write main amplifier will need to amplify 0.4V to 0.7.

### SUMMARY OF THE INVENTION

It is an aspect of the present invention to provide a low voltage and low power embedded SRAM system having high throughput for at-memory compute architecture AI chips where the SRAM is located on-chip adjacent to the processing element of the at-memory compute architecture. The SRAM therefore operates at two different voltage domains, roughly speaking; memory read voltage and a processing element coupled circuit voltage (vddp) of 0.4 and memory write voltage of 0.7V.

In conventional SRAM, the write amplifier and read amplifier are placed at the nearest side to PE. In this scheme, the length of the of BL lines becomes long because the BLs go through the insides both write and read amplifiers. Long BLs impact the BL power consumption which will occupy the majority of SRAM power consumption, and read signal speed. Therefore, according to an aspect of the invention, the write amplifier or write main amplifier (WMA) is located at the opposite side of read main amplifier (RMA) which is located at the PE side.

It is a further aspect of the present invention to provide an SRAM embedded in an AI chip that operates at low voltage and low power during read operations, which occur more often than write operations.

In another aspect, a method and apparatus for charge sharing are set forth using segmented bit lines.

Additionally, a method and apparatus for seamless read operation is set forth without any segmented sub arrays, as well as separated read and write main amplifier.

These together with other aspects and advantages which will be subsequently apparent, reside in the details of construction and operation as more fully hereinafter described and claimed, reference being had to the accompanying drawings forming a part hereof, wherein like numerals refer to like parts throughout.

### BRIEF DESCRIPTION OF THE DRAWINGS

FIG. 1 shows a SRAM cell array according to the prior art.

FIG. 2 shows a 6T SRAM cell array, according to an embodiment.

FIG. 3A shows an array of 6T SRAM bit cells shown in FIG. 2, write main amplifiers (WMAs), read main amplifiers (RMAs), latches and a 4:1 multiplexer, according to an embodiment.

FIG. 3B shows a series connection of 6T SRAM bit cells, write main amplifiers (WMAs), read main amplifiers (RMAs), latches and 4:1 multiplexers of FIG. 3A to increase array density with a doubling of the number of rows while retaining the same number of columns, according to an embodiment.

FIG. 3C shows a cross-coupled NMOS circuit (CP_NMOS), according to an embodiment of the 6T SRAM bit cell shown in FIG. 3A.

FIG. 3D shows an embodiment of the read main amplifier, shown in FIG. 3A.

FIG. 3E shows an embodiment of the write main amplifier, shown in FIG. 3A.

FIG. 4 shows dependency of bit line precharge power on precharge level (voltage).

FIG. 5A shows a bit line charge sharing circuit to generate a low BL precharge level, according to an embodiment.

FIG. 5B is a simplified timing diagram showing operation of the bit line charge sharing circuit of FIG. 5A.

FIG. 5C is a simplified timing diagram similar to FIG. 5B showing word line transitions during operation of the bit line charge sharing circuit of FIG. 5A.

FIG. 5D and FIG. 5E are detailed timing diagrams showing operation of the charge sharing circuit of FIG. 5A for adjusting the bit line (BL) precharge level from write to read operations.

FIG. 5F is a simplified timing diagram showing operation of the cross-coupled NMOS circuit shown in FIG. 3A within the charge sharing circuit of FIG. 5A.

FIG. 5G shows a cross-coupled NMOS circuit (CP_NMOS), according to further embodiment of the 6T SRAM bit cell shown in FIG. 3A.

FIG. 5H is a simplified timing diagram showing operation of the cross-coupled NMOS circuit of FIG. 5G.

FIG. 6A shows a negative Vss_cell generator according to an embodiment, and FIG. 6B is a timing diagram thereof.

FIG. 7 shows a 6T SRAM cell array, according to an embodiment wherein a latch is placed in each column.

FIG. 8 is a timing diagram showing operation of the 6T SRAM cell array of FIG. 7.

FIG. 9 shows series connection of two vddp supply source to generate vdd_cell, in order to minimize the number of supply sources, according to an embodiment.

### DETAILED DESCRIPTION OF THE PREFERRED EMBODIMENTS

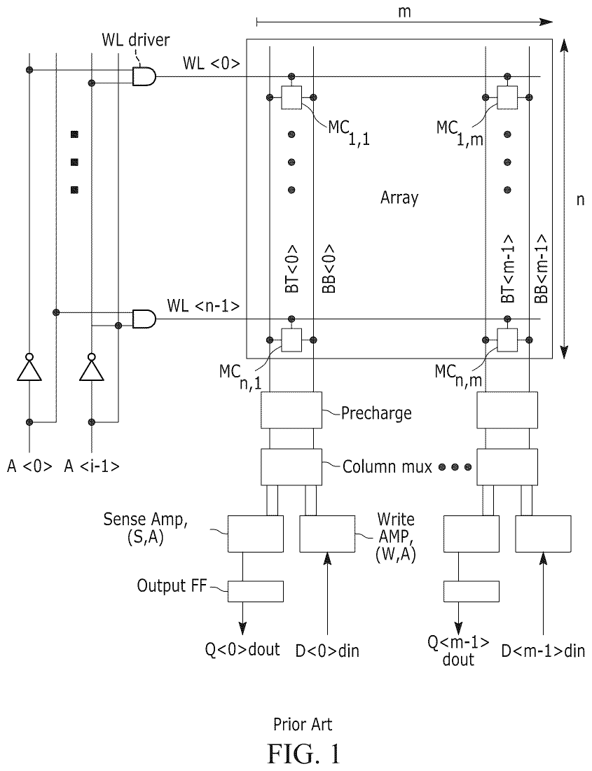

A conventional SRAM cell array is shown in FIG. 1, comprising a plurality of SRAM cells MC_{1,1} . . . MC_{1,m} . . . MC_{n,1} . . . MC_{n,m}, to which binary data (dout, din) is read/written on bit lines BT<0>/BB<0> . . . BT<m−1>/BB<m−1> via column precharge, multiplexers (column mux), and sense/write amplifiers ((S.A.) and W.A., respectively), in response to read/write signals applied to word lines WL<0> . . . WL<n−1> by a word line (WL) driver.

As discussed above, PCT/IB2022/055760 sets forth a method and apparatus for half-Vdd bit line precharge in 6T SRAM memory cells to reduce the bit line precharge power, compared with conventional Vdd bit line precharge schemes. In operation, the method and apparatus of PCT/IB2022/055760 provides one half bit line-power during read and write operations with halved bit line-swing. According to an additional aspect of PCT/IB2022/055760, a further low power configuration is provided for reducing the bit line high voltage level from Vdd to a reduced voltage (Vddr) by means of a Vddr generator. A major advantage of the half-Vdd bit line precharge scheme of PCT/IB2022/055760 is very easy generation of the half-Vdd voltage level by shorting bit lines BL and BLB.

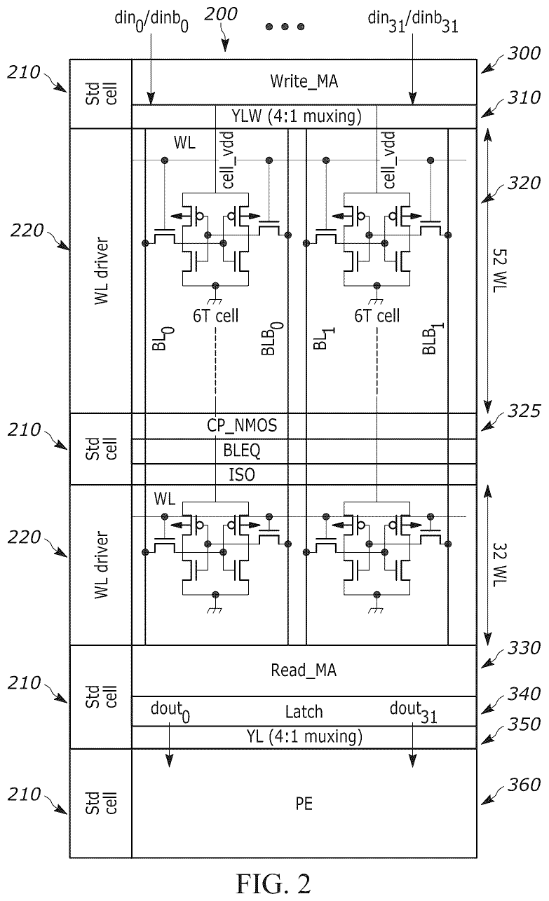

As discussed above, the write amp and read amp are placed at the nearest side to PE, such that the length of the of BL lines becomes long due to their passing through the inside of both write and read amplifiers. Long BL lines impacts BL power consumption which consumes the majority of SRAM power, as well as read signal speed. Therefore, according to an embodiment, the write amplifier or write main amplifier (WMA) is located at an opposite side of read main amp (RMA) at the PE side, as shown in FIG. 2.

FIG. 2 shows an array 200 of 6T SRAMs embedded in an at-memory architecture, and connected to I/O peripheral circuits 210 in the form of standard cells operating in the standard memory voltage domain, and word line (WL) drivers 220 for driving Word Lines (WL_{L} and WL_{R}) according to an embodiment. The array 200 comprises write main amplifier (WMA) 300, input 4:1 multiplexer 310, plurality of 6T Bit Cells 320, cross-coupled NMOS circuit (CP_NMOS) 325, read main amplifier (RMA) 330, latch 340 and output 4:1 multiplexer 350 connected to a Processing Element (PE) 360 of the at-memory compute architecture. Additional details of 6T Bit Cell 320, cross-coupled NMOS circuit (CP_NMOS) 325, read main amplifier 330, latch 340 and output 4:1 multiplexer 350 are discussed below.

In order to minimize capacitance on the bit lines (BLs) and reduce power during read operations, which occur more often than write operations in AI chips, the read path of the bit lines connect to read main amplifier 330 which is connected directly to processing elements 360 resulting in a simple, short but line path with minimal additional capacitance, by write main amplifiers are placed at the opposite side of the read main amplifier.

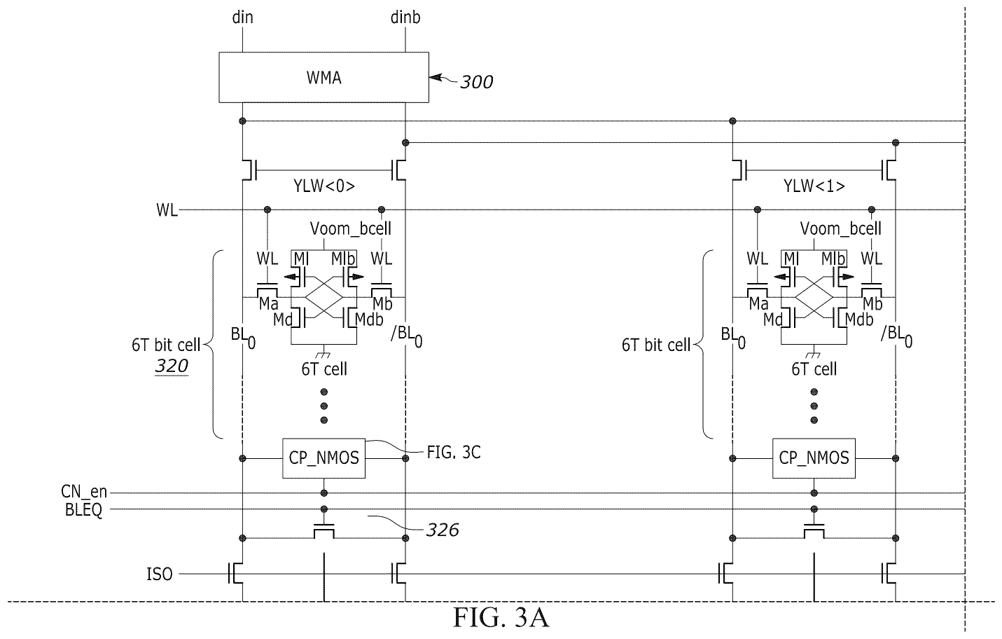

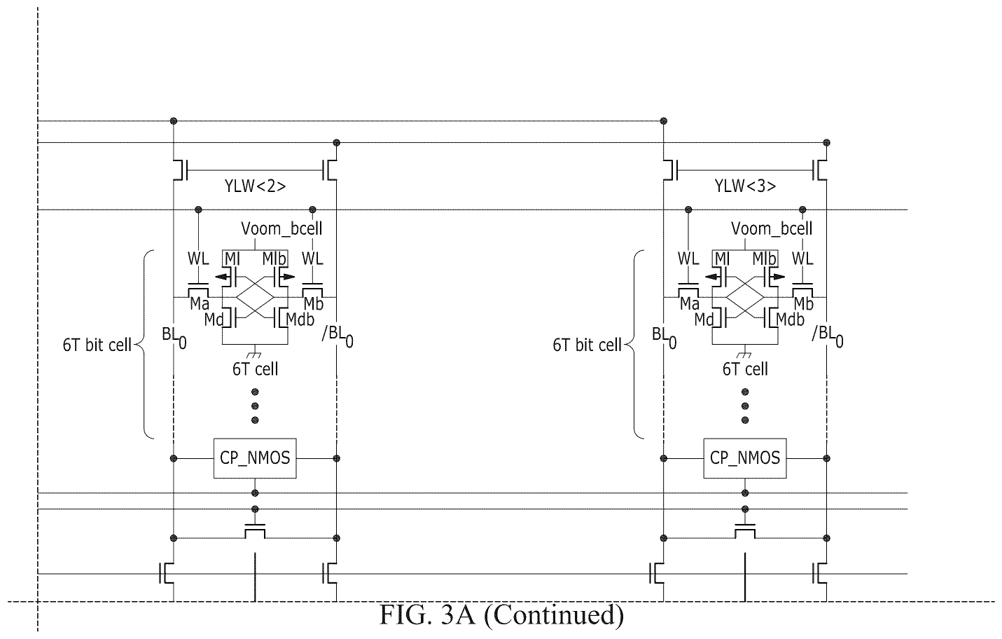

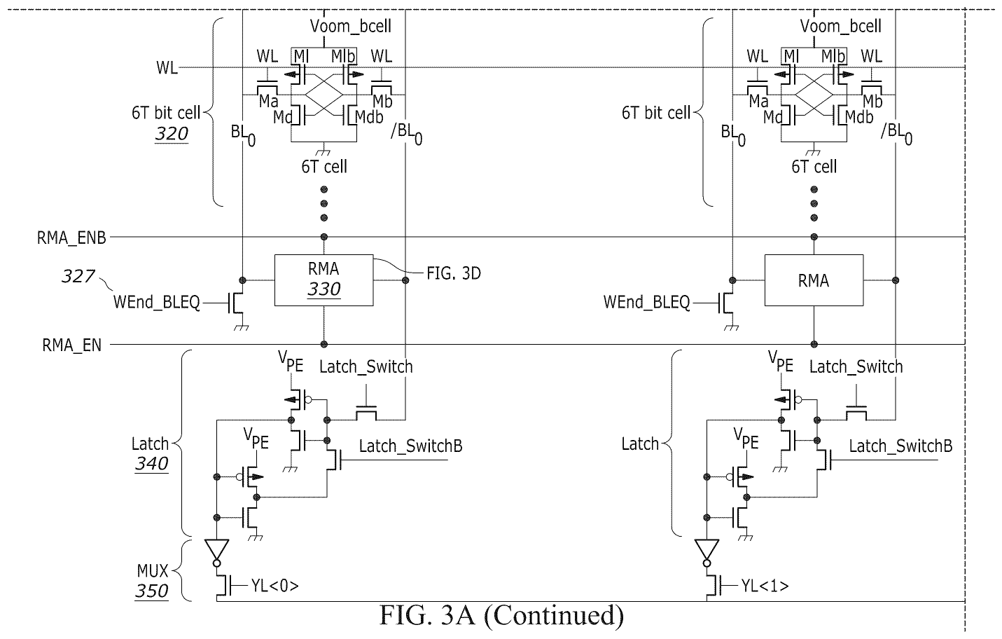

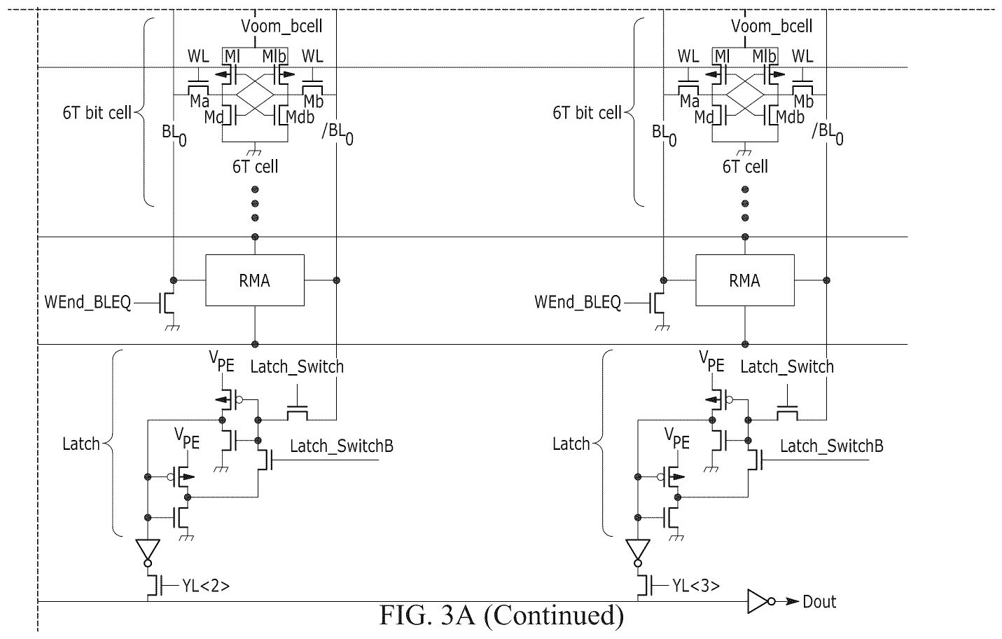

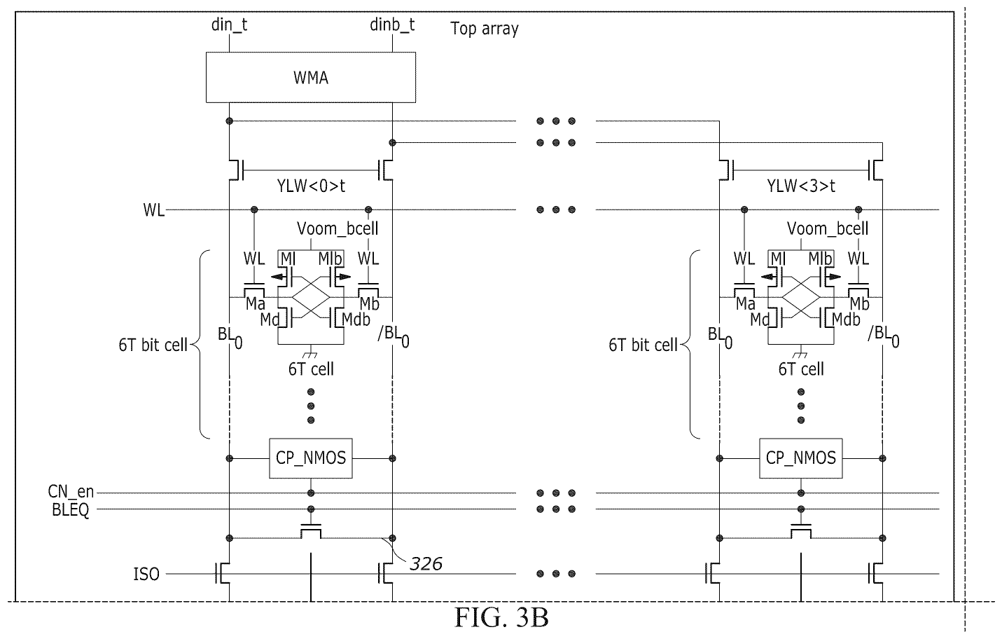

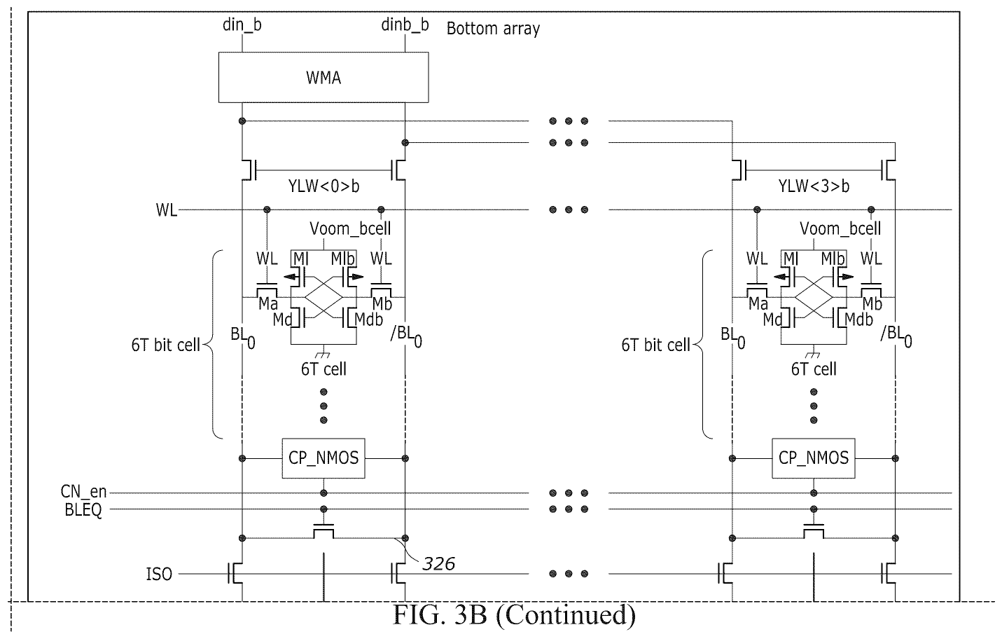

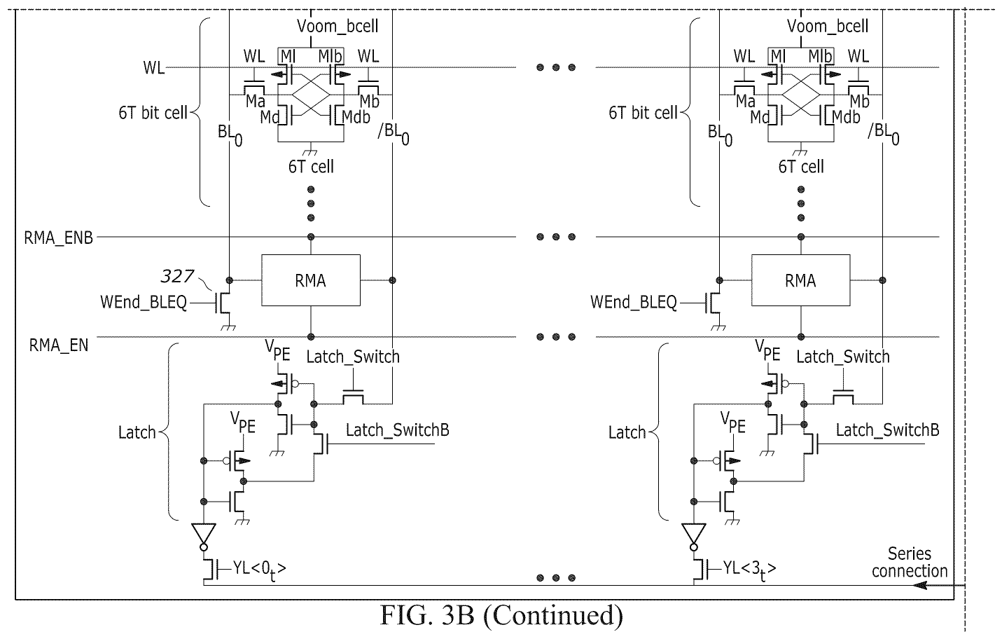

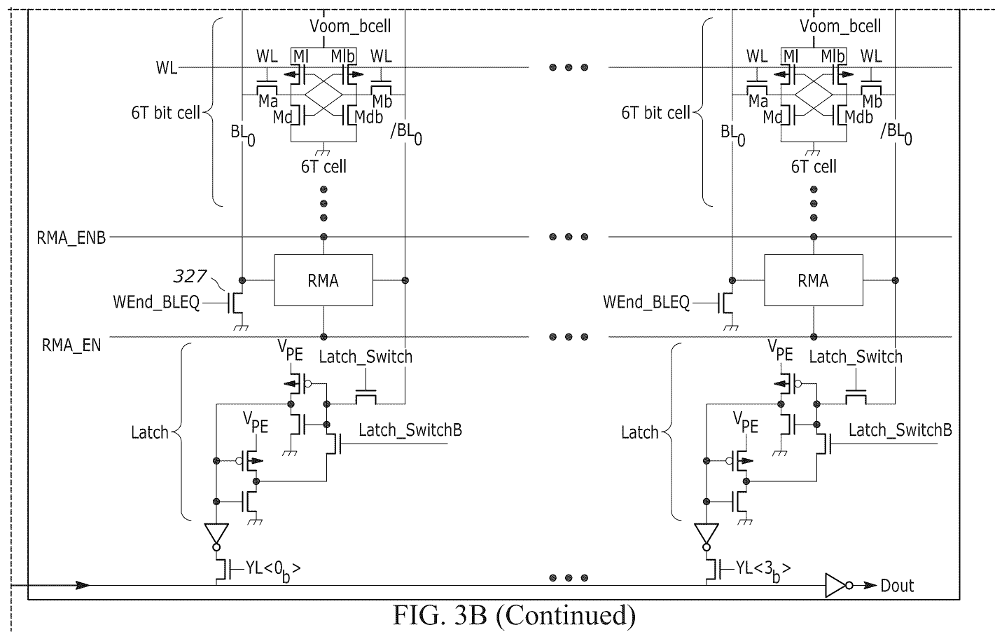

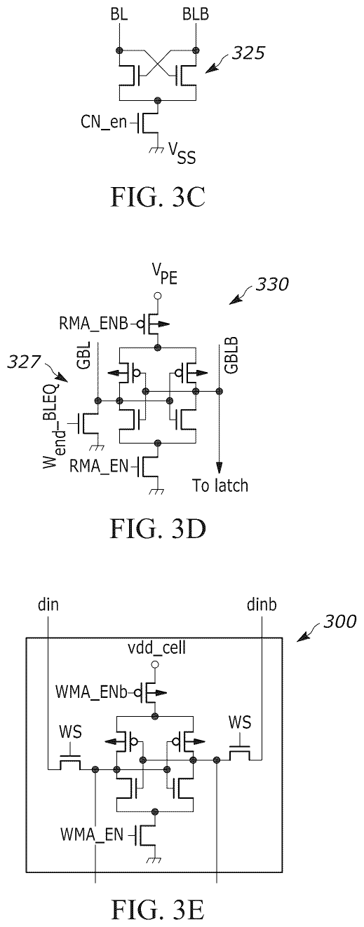

FIG. 3A shows details of an array of 6T SRAM bit cells 320 shown in FIG. 2, write main amplifier (WMA) 300, read main amplifiers (RMA) 330, latches 340 and a 4:1 multiplexer 350, according to an embodiment. For an array of 80 rows×128 columns, there are 32 data outputs (Dout₀ . . . Dout₃₁, as shown in FIG. 2) because of the 4:1 multiplexor 350 and four PEs with x8 I/O, such that each PE has 320B (=80×128/4/8).

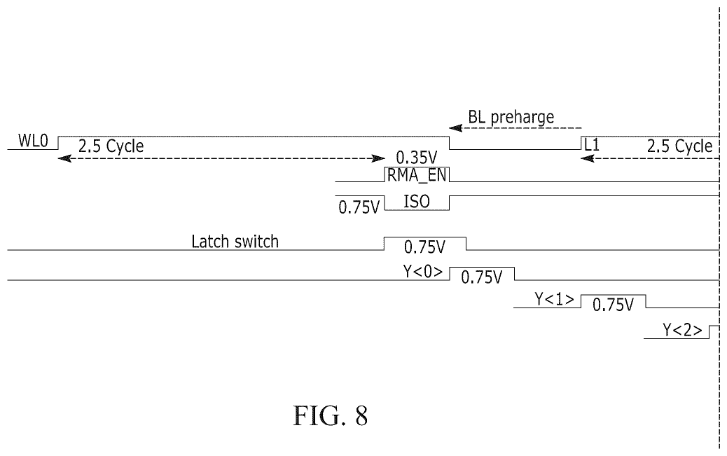

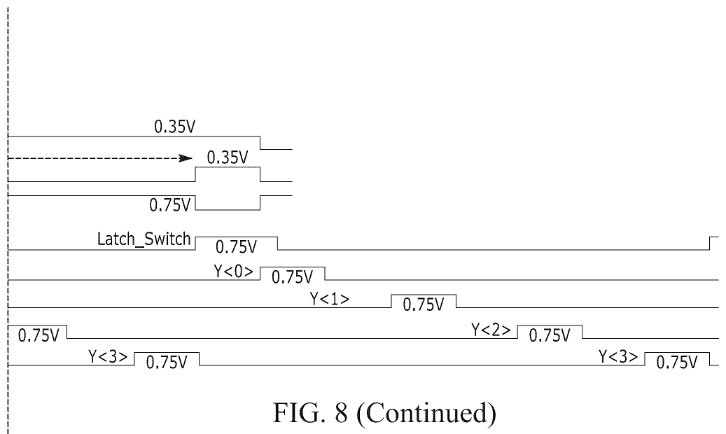

In order to double the PE density of 320B to 640B/PE, a simple series connection of arrays can be provided, as shown in FIG. 3B, where the prestage node of the Dout inverter allows for a simple wired-or connection. Simultaneous write to the bottom array and read from the top array, or vice versa, is possible using the configuration of FIG. 3B, wherein the read operation can be made seamless using the latch 340, as described in greater detail below with reference to FIG. 8.

FIG. 3C shows details of cross-coupled NMOS circuit 325, according to an embodiment of the 6T SRAM bit cell shown in FIG. 3A.

FIG. 3D shows details of an embodiment of the read main amplifier 330, shown in FIG. 3A.

FIG. 3E shows details of an embodiment of the write main amplifier 300, shown in FIG. 3A.

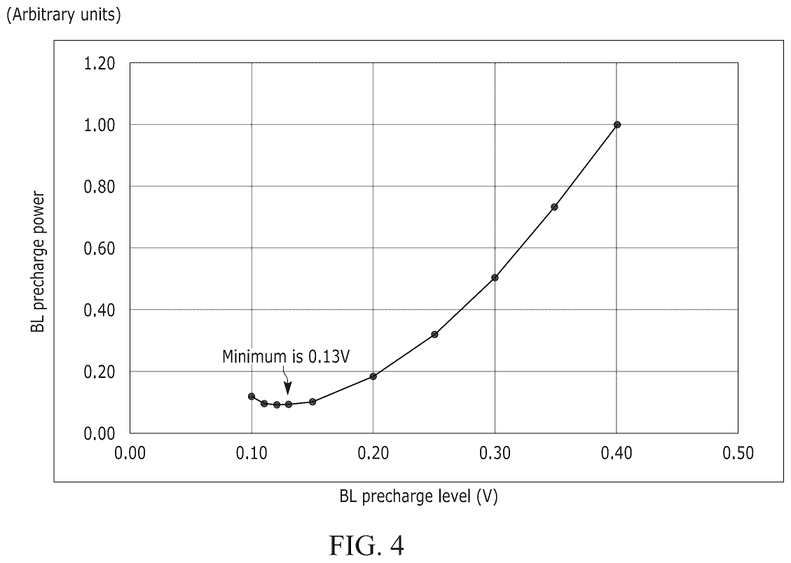

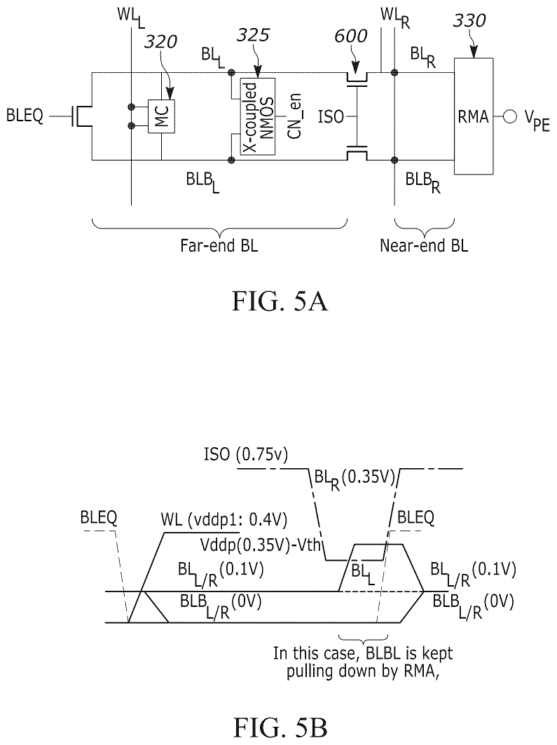

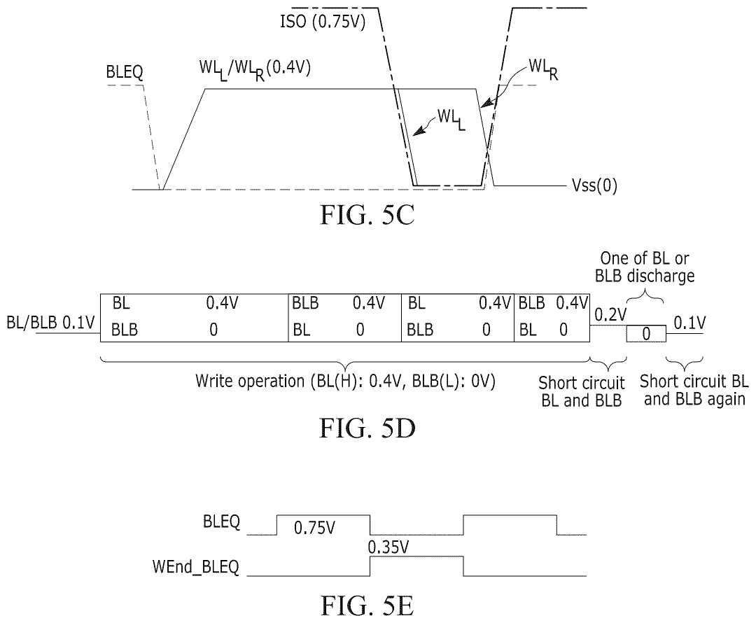

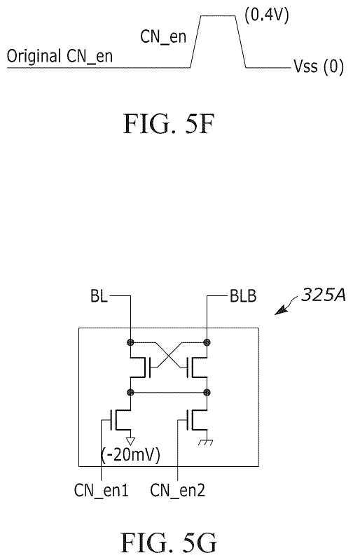

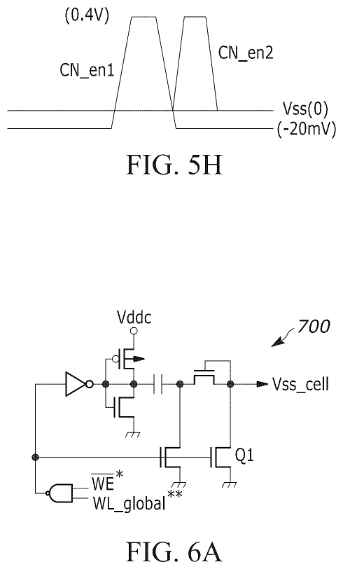

FIG. 4 shows the dependency of bit line precharge power on precharge level (voltage), from which it will be seen that a 0.13V (˜0.1V) precharge level provides minimum power consumption. To set the bit line precharge level to 0.1V with low power consumption for a processing element domain voltage of, for example, 0.354V, a charge sharing scheme is provided wherein, according to an embodiment, the bit line is partitioned into two portions BL_{L}, BLB_{L} and BL_{R}, BLB_{R} by an isolation (ISO) switch 600, as shown in FIG. 5A. During bit line precharging, the two bit line portions are connected by closing the ISO switch 600. Once the read out operation starts and the read signal reaches about 100 mV, the two bit line portions are separated by opening ISO switch 600, and the shorter bit line portion BL_{R}, BLB_{R} adjacent to the read main amp 350, is amplified rail-to-rail, for example, from vss to vddp (0.354V), as shown in FIG. 5B. After the read out operation, the two portions of the bit line are connected by closing ISO switch 600, such that charge sharing occurs from the shorter bit line portion BL_{R}, BLB_{R}, amplified to vddp, to the longer portion BL_{L}, BLB_{L}, which stays at a level lower than vddp, to generate the 0.1V bit line precharge level. Thus, the purpose of closing ISO switch 600 is to separate the two portions of the bit line when the shorter portion adjacent to RMA 330 is amplified to vddp, which is not required to be at the vss level of ISO switch 600, but is required at most at the vddp-vth level to avoid amplified vddp level degradation. Setting the ISO switch 600 to the low level (vddp-vth) results in RMA 330 pulling down the voltage of the long portion of the bit line.

As shown in FIG. 5C, the “far end” word lines WL_{L} (i.e. on the far-end of the bit line segmented by the ISO switch 600 from RMA 330) turns off just after ISO switch 600 separates the two segmented bit lines in order to reduce the bit cell currents induced by the high state of the far-end segmented bit line, for example, 0.1V. The width of the word lines WL_{R} on the “near-end” of the segmented bit lines turns off just before bit line precharge starts as a result of assertion of the BLEQ signal, as shown in FIG. 5C.

In an embodiment, the bit line partition ratio can be calculated as follows: if the bit line capacitance is 10 fF and the capacitance of the read main amplifier 330 is 0.2 fF, from the law of conservation of charge, C(BL_{L})×0.1+(C(BL_{R})+0.2)×0.4=2 C(BL_{L})×0.1+2 (C(BL_{R})+0.2)×0.1. To solve this equation using C(BL_{L})+C(BL_{R})=10 fF, the capacitance partitioning of BL should be C(BL_{L})=6.8 fF and C(BL_{R})=3.2 fF.

During write operations, BL and BLB are floating by opening the BLEQ short NMOS 326 and applying a write voltage (e.g. voltage step from vss=0V to vdd_cell=0.7V). Then, after the write operation, BLEQ NMOS 326 short circuits BL and BLB such that the BL precharge level becomes vdd_cell/2. In order to adjust the BL precharge level from write to read, the BL that is precharged at vdd_cell/2 after write is discharged to vss by Wend BLEQ NMOS 327, and then BLEQ NMOS 326 short circuits bit lines BL and BLB again such that the new BL precharge level becomes half of vdd_cell/2, or vdd_cell/4. Thus, for the example of vdd_cell=0.7V, then vdd_cell/4=0.175V. If the read BL precharge level needs to be set at 0.1V, the 91 of Wend BLEQ NMOS 327 should be turned on to discharge the BLs instead of 64(=128/2). In summary, according to embodiments, the BL precharge level can be 0.1V˜0.15V during read operations and vdd_cell/2, where vdd_cell/2>0.15V, during write operations by short circuiting BL and BLB twice using BLEQ NMOS 326 to adjust the two different BL precharge levels. Timing diagrams for operation of BLEQ NMOS 326 and Wend_BLEQ NMOS 327 to achieve the required precharge BL levels during write and read operations, are shown in FIGS. 5D and 5E.

In the case that WL_{R} is selected and the operating conditions are at the slowest process corners and/or at temperatures where transistors are the slowest etc., BLB_{L} will not be pulled down to Vss completely, through the bit-cell access transistors controlled by WL_{R}, before the ISO switch 600 is opened (assuming the data value is such that BL=High and BLB=Low). In order to obtain a Vpre_read=0.1V BL precharge level through charge sharing, the voltage of BLB_{L} needs to be pulled down to Vss. Therefore, as shown in FIG. 5A, cross-coupled NMOS circuit 325 can be provided between BL_{L} and BLB_{L}. The cross-coupled NMOS circuit 325 pulls down the voltage of BLB_{L} to Vss without requiring assistance of the bit-cell selected by WL_{R}. FIG. 5F is a simplified timing diagram showing operation of the cross-coupled NMOS circuit 325.

In the event that the threshold voltage of the cross-coupled NMOS circuit 325 becomes too high to discharge BL due to process variation etc., the source of the cross-coupled NMOS circuit, which is set to Vss, can be pulled down to a negative bias for a period of time (e.g., one half cycle), and then returned to Vss. Therefore, an alternative embodiment of cross-coupled NMOS circuit 325A can be provided, as shown in FIG. 5G where the source can be pulled down to −20 mV by a control signal CN_en1, as shown in FIG. 5H.

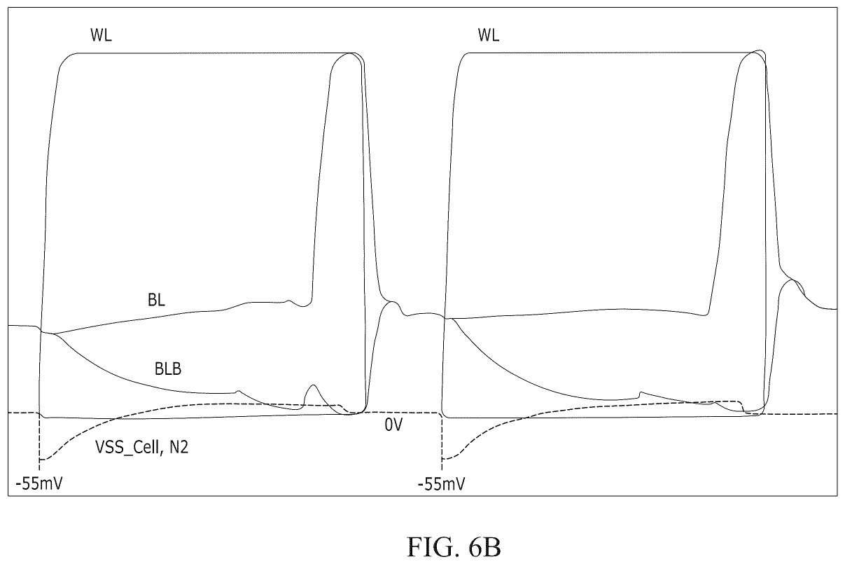

When the bit line precharge level is at a low voltage, such as 0.1V, and the word line read voltage from the WL driver 220 is 0.4V, the high store node of the 6T SRAM bit cell 320 cannot significantly pull the voltage of one of the bit lines BL up from 0.1V. On the other hand, the low store node of 6T SRAM bit cell 320 tries to pull down the other BL toward vss. Accordingly, a negative Vss_cell generator 700 can be provided, as shown in FIG. 6A for pulling down vss to a negative voltage, such as −55 mV, which allows the BL voltage to be pulled down, resulting in strong tolerance to variations in bit cell transistor conductance. During write operations, /WE is low such that Vss=0 due to Q1, while during read operations each time the WL_global signal is asserted one-shot charge pumping produces a negative Vss_cell voltage, as shown in FIG. 6B.

The word line (WL) voltage impacts the bit cell data hold margin during read operations, and the write margin during write operations. In order to enhance the write margin, a higher word line voltage is preferred during write operations, and a lower word line voltage is preferred to enhance the bit cell data hold margin during read operations, although if the word line voltage is too low data cannot be read out from the bit cell 320. According to an embodiment, a two-step word line (WL) signal is generated by the word line driver 220 having a lower WL voltage (e.g. 0.4V) during read operations, and during write operations a first portion of the WL signal is made the same voltage as during read operations by performing a “pseudo read” via a masked write or no write operation in write mode, and thereafter the WL signal is boosted to a higher voltage to enhance writability. In the event of a masked write, the bit cell vdd of the masked write column remains at the same voltage as that during read operations. For example, the first step of the two-step WL signal during write operations can be at vddp while the second step can be at vdd_cell, whereas the WL signal can be at vddp during read operations. The WL signal drops to 0V when data (Dout) on the word line (WL) is transferred to latch 340, and BL precharging then commences for reading the data on the next assertion of the WL signal.

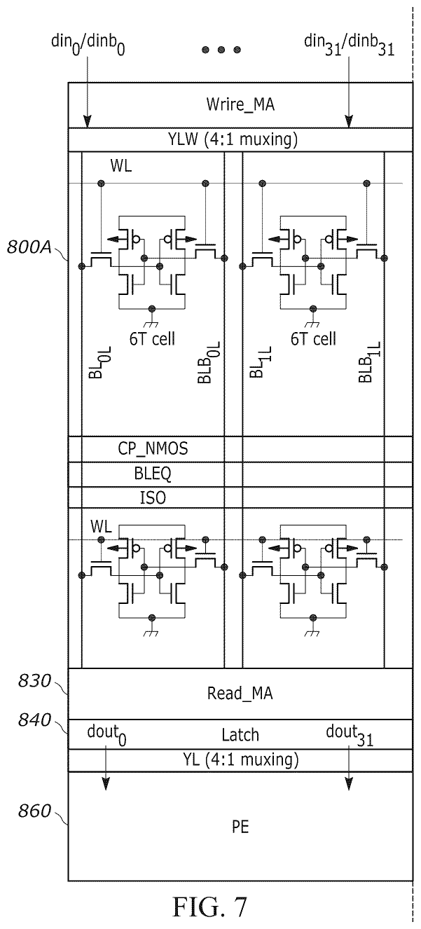

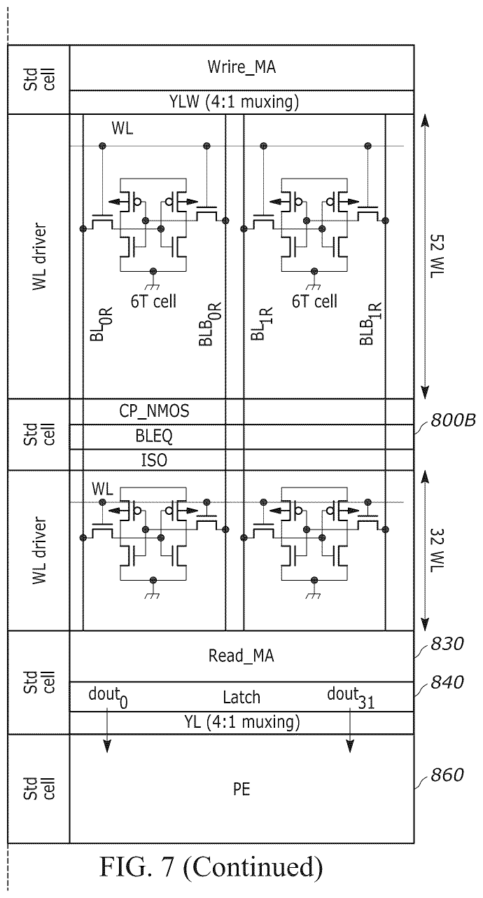

Ping-pong operation between two separate sub-arrays realizes seamless read, conventionally, but adds to cost in terms of additional layout area between two subarrays and to complexity in terms of timing. On the other hand, one large array, such as shown in FIG. 2, is simple and effective from a circuit design and layout area viewpoint, provided seamless read can be achieved without ping-pong operation. In accordance with an embodiment, as shown in FIG. 7, a common word line driver is located between sub-arrays 800A and 800B, which are provided with a latch 840 in the column of each array. After all bits on a word line (WL) are amplified by the read main amp (RMA 830) and its output is transferred to the latch 840, the word line can be turned off and the other word line can be turned on to amplify the data by read main amp 830, while the latch 840 is outputting the data to the processing element 860. Seamless read operations are therefore possible in this way, without ping-pong operation between two different subarrays, as shown in the timing diagram of FIG. 8, where the word line (WL) signal drops to 0V when data (Dout) on the word line is transferred to the latch 840, and bit line precharging commences for reading the data on the next assertion of the word line signal.

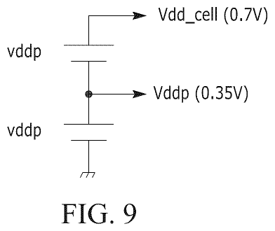

In order to minimize the number of supply sources, which lowers cost, two vddp supply sources can be series connected, as shown in FIG. 9 to generate vdd_cell.

The many features and advantages of the invention are apparent from the detailed specification and, thus, it is intended by the appended claims to cover all such features and advantages of the invention that fall within the true spirit and scope of the invention. Further, since numerous modifications and changes will readily occur to those skilled in the art, it is not desired to limit the invention to the exact construction and operation illustrated and described, and accordingly all suitable modifications and equivalents may be resorted to, falling within the scope of the invention.

What is claimed is:

1. A static random access memory (SRAM) embedded in an at-memory architecture with a processing element (PE) operating at a processing element (PE) domain voltage vddp, comprising:
a bit cell having a pair of bit lines (BL) and a word line (WL), said bit cell operating at a bit cell write voltage vdd_cell which is set to the writing voltage; and a bit line (BL) precharge circuit for generating a bitline precharge voltage of vdd_cell/2 during write operations, and a bitline precharge voltage of 0.1V˜0.15V during read operations, where vdd_cell/2>0.15V.

2. The SRAM of claim 1, further comprising a read main amplifier (RMA) and a write main amplifier (WMA) located at an opposite side from the read main amplifier (RMA), for amplifying a data line (din) voltage from the PE domain voltage, vddp, to vdd_cell.

3. The SRAM of claim 2, wherein the bit line (BL) precharge circuit includes an isolation (ISO) switch for selectively partitioning the pair of bit lines (BL) into a far end from a side segment of the processing element (PE) and a near end from the side segment of the processing element (PE) such that the near end is amplified rail-to-rail by the read main amplifier (RMA) when the isolation (ISO) switch is open and a read precharge voltage of 0.1V˜0.15V is generated for charge sharing between the pair of bit lines (BL) when the isolation (ISO) switch is closed.

4. The SRAM of claim 3, further comprising a cross-coupled NMOS, wherein the isolation (ISO) switch is operable to adjust the bit line (BL) precharge voltage from vdd_cell/2 during write operations to vdd_cell/4 during read operations by twice short circuiting the two bit line (BL) portions via the cross-coupled NMOS switch for charge sharing between the two bit line (BL) portions.

5. The SRAM of claim 4, further comprising a word line (WL) driver for generating a two-step word line signal during write operations, wherein a first step is at a word line voltage of vddp1, and a second step is at vdd_cell, where vdd_cell>vddp1, and generating a single step word line signal at vddp1 during read operations.

6. The SRAM of claim 5, further comprising a negative Vss_cell generator for pulling down a vss voltage of the bit cell to a negative voltage by implementing a one shot pulse during read operations, and maintaining vss at 0V during write operations.

7. The SRAM of claim 2, further comprising a read main amp (RMA) and latch disposed at every column on one side of processing element (PE), and data lines (din/dinb) input to the bit line (BL) through the write main amplifier WMA from an opposite side of processing element (PE).

8. The SRAM of claim 5, wherein the word line (WL) driver causes the word line signal to drop to 0V when data (Dout) on the word line (WL) is transferred to the latch, and wherein the bit line (BL) precharge circuit starts precharging the bit line (BL) for reading the data (Dout) on a next assertion of the word line signal.

9. The SRAM of claim 4, wherein the cross-coupled NMOS is located in the far end segment of the bit line partitioned by the isolation (ISO) switch from the read main amp (RMA).

10. The SRAM of claim 9, wherein a source of the cross-coupled NMOS is pulled down to a negative bias voltage for a period of time and thereafter returned to Vss.

11. The SRAM of claim 10, wherein the negative bias is −20 mV.

12. The SRAM of claim 10, wherein the period of time is a half cycle.

13. The SRAM of claim 4, wherein each word line (WL) in the far end segment has a different width than each word line (WL) in the near end segment, and wherein each word line (WL) in the far-end segment is turned-off after the isolation (ISO) switch partitions the bit lines (BL).

14. The SRAM of claim 5, wherein vddp1=0.4V.

15. The SRAM of claim 4, wherein the amplitude of the ISO signal for partitioning the bit lines (BL) is from vddp-Vth to vddp during read, and Vdd_cell is fixed during write, being the second step word line voltage.

16. The SRAM of claim 2, wherein vdd_cell is generated by series connection of two power supply, vddp.
